(19) United States
(12) Patent Application Publication
(10) Pub. No.: US 2011/0006191 A1
(43) Pub. Date: Jan. 13, 2011

(54) IMAGE CAPTURE APPARATUS AND RADIATION IMAGE CAPTURE SYSTEM

(75) Inventors: Minoru Watanabe, Honjo-shi (JP); Chiori Mochizuki, Sagamihara-shi (JP); Takamasa Ishii, Honjo-shi (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/793,876

(22) Filed: Jun. 4, 2010

(30) Foreign Application Priority Data
Jul. 13, 2009 (JP) 2009-165049

(51) Int. Cl. H01L 27/148

(52) U.S. Cl. 250/208.1

(57) ABSTRACT

An image capture apparatus includes a plurality of pixels, each including a plurality of thin film transistors (T1, T2) having different operating resistances and a photo-electric conversion element (C11), a selection unit configured to select at least one of the thin film transistors, and a signal line (S1) on which electric charge generated by the photo-electric conversion elements is output via the thin film transistors selected by the selection unit.

### BACKGROUND OF THE INVENTION

1. Field of the Invention

The present invention relates to an image capture apparatus that includes thin film transistors (TFTs).

2. Description of the Related Art

In recent years, liquid crystal panels using TFTs (thin film transistors) are used also as image capture apparatus or radiation image capture apparatus in which TFTs and photo-electric conversion elements are used in combination. Their driving speeds are also diversifying, and methods for switching the capacity of the elements in accordance with the drive frequency so as to control the time constant have been proposed, as described in Japanese Patent Laid-Open No. 9-261538.

However, with the configuration described in Japanese Patent Laid-Open No. 9-261538, there is the problem that increasing the capacity of the elements in order to increase the time constant may have adverse effects on characteristics, such as an increase in KTC noise.

### SUMMARY OF THE INVENTION

The present invention has been made in view of the aforementioned issue and enables an image capture apparatus configured by combining TFTs and a conversion element to reduce artifacts in a moving image mode and reduce noise in a still image mode, thereby obtaining good images in the shooting modes.

According to first aspect of the present invention, there is provided an image capture apparatus comprising a plurality of pixels, each including a plurality of thin film transistors having different operating resistances and a photo-electric conversion element, a selection unit configured to select at least one of the plurality of thin film transistors, and a signal line on which electric charge generated by the photo-electric conversion elements is output via the thin film transistors selected by the selection unit.

According to second aspect of the present invention, there is provided a radiation image capture system comprising an image capture apparatus recited above and a signal processing unit configured to process a signal from the image capture apparatus.

Further features of the present invention will become apparent from the following description of exemplary embodiments with reference to the attached drawings.

### BRIEF DESCRIPTION OF THE DRAWINGS

FIG. 1 is a simplified equivalent circuit diagram of an image capture apparatus according to a first embodiment of the present invention.

FIG. 2 is another simplified equivalent circuit diagram of the image capture apparatus according to the first embodiment of the present invention, showing a different example from that in FIG. 1.

FIG. 3 is a plan view of a pixel in the image capture apparatus according to the first embodiment of the present invention.

FIG. 4 is a simplified equivalent circuit diagram of an image capture apparatus according to a second embodiment of the present invention.

FIG. 5 is a plan view of a pixel according to the second embodiment of the present invention.

FIGS. 6A and 6B are plan views of a pixel according to the second embodiment of the present invention, FIG. 6A showing a different example from that in FIG. 5 and FIG. 6B showing an intermediate step in forming the pixel in FIG. 5.

FIG. 7 is a drive timing chart according to the second embodiment of the present invention.

FIGS. 8A and 8B are a schematic block diagram and a schematic cross-sectional view, respectively, of an embodiment of an X-ray image capture apparatus according to the present invention.

FIG. 9 is an illustrative diagram showing an example in which the X-ray image capture apparatus according to the present invention is applied to an X-ray diagnostic system.

### DESCRIPTION OF THE EMBODIMENTS

The following is a detailed description of embodiments of the present invention with reference to the accompanying drawings.

### First Embodiment

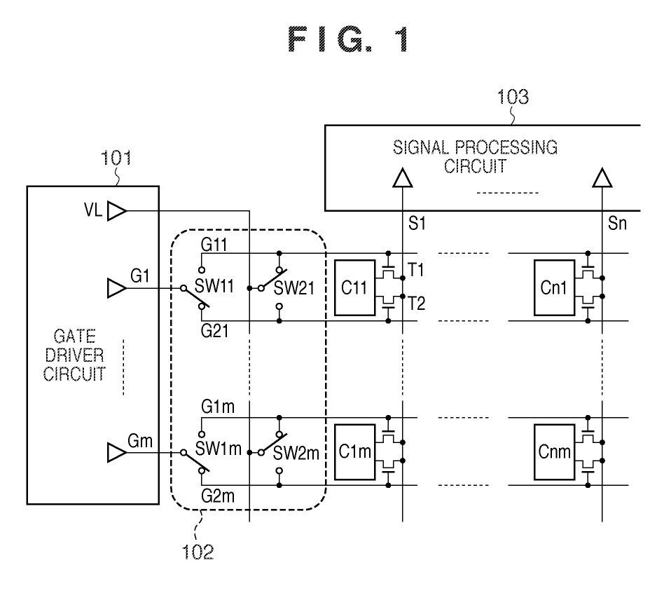

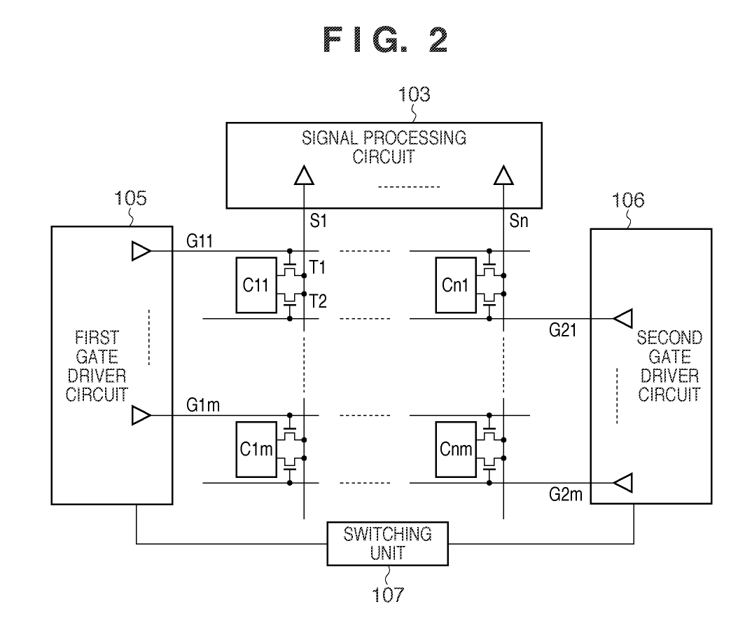

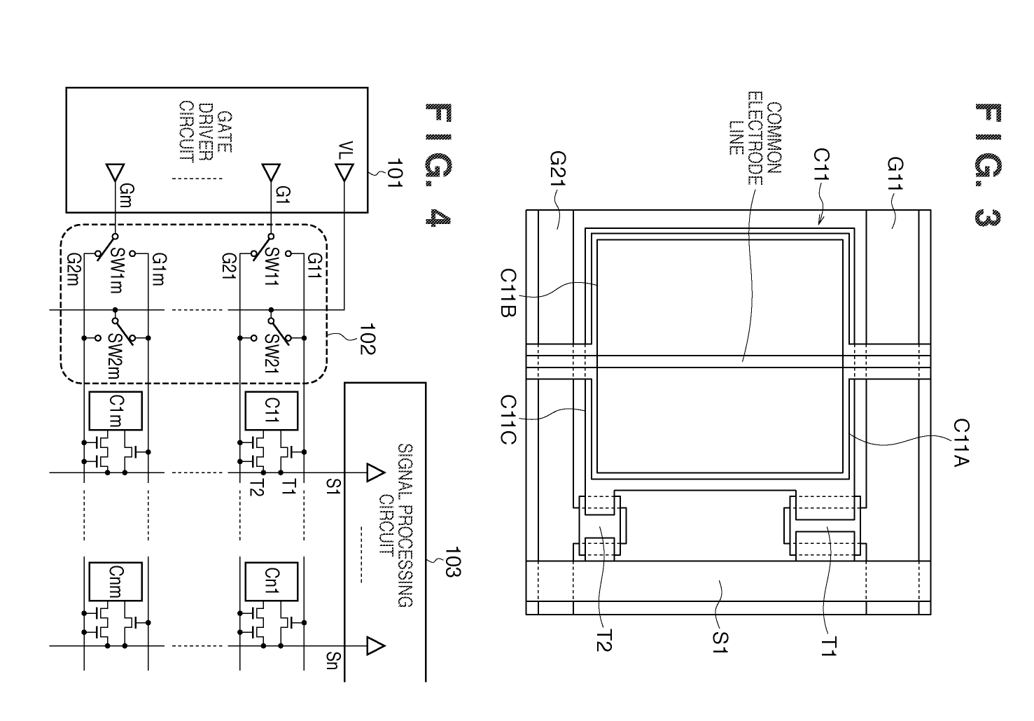

A first embodiment of the present invention is described with reference to FIGS. 1 to 3. FIG. 1 is a simplified equivalent circuit diagram of an image capture apparatus according to the first embodiment of the present invention. FIG. 2 is another simplified equivalent circuit diagram of the image capture apparatus according to the first embodiment of the present invention, which shows a different example from that in FIG. 1. FIG. 3 is a plan view of a pixel in the image capture apparatus according to the first embodiment of the present invention. The image capture apparatus of the present embodiment includes a conversion element for converting light such as visible or infrared light or radiation such as X-rays, α-rays, β-rays, and γ-rays into an electric signal. The following describes an image capture apparatus that uses, as a conversion element, a photo-electric conversion element for converting light into an electric signal.

Referring to FIG. 1, a photo-electric conversion element C11 is connected to a signal line S1 via a first thin film transistor (hereinafter referred to as a “TFT”) T1 and a second TFT T2, and a signal from the photo-electric conversion element C11 is output to a signal processing circuit 103. The first TFT T1 is controlled by a voltage supplied through a first gate line G11, and the second TFT T2 is controlled by a voltage supplied through a second gate line G21. The first gate line G11 and the second gate line G21 are selectable with a switching unit 102 that is disposed between a gate driver circuit 101 disposed on the periphery and a pixel area.

In an image capture apparatus used in particular for radiation (radiation image capture apparatus), the transfer capability of TFTs is an important factor in a moving image mode. This is for the following reasons: In the moving image mode, a human body is continuously irradiated with X-ray radiation and thus the radiation dose per unit time is set to be smaller than in a still image mode in order to reduce the dose of X-rays. Also in the moving image mode, since the frame rate is high and accordingly the dose of X-rays being emitted per frame is extremely low, the number of carriers generated by incident X-rays is very small compared to that in the still image mode. Hence, a TFT transfer capability that enables a small number of carriers to be reliably transferred within a short time is required in the moving image mode.

In contrast, in the still image mode where a higher dose of X-rays than in the moving image mode is emitted to a human body and it takes a longer time to transfer carriers than in the moving image mode, enhanced image quality through highly accurate reading is an important factor. In particular, in cases such as where the still image mode is used for diagnostic shooting after alignment of a human body, an enhancement of image quality is required in the still image mode in order to prevent a retake and thereby reduce the dose of X-rays emitted to the human body.

Here, Patent Laid-Open No. 9-261538 discloses a photo-detecting device, in which an open/close switch for controlling circuit connections of an auxiliary capacity to a pixel capacity is provided, and the open/close switch is operated so as to control a time constant at the time of reading an accumulated electric charge. However, when the pixel capacity and the auxiliary capacity are connected in such a configuration, the increased pixel capacity causes an increase in KTC noise (thermal noise) proportional to the capacity and in particular, an increase in noise in the still image mode in which the time constant is increased. Alternatively, even if the same TFTs as used in the moving image mode are used in the still image mode so as to increase the time constant, the same TFT leakage current occurs and thus, noise corresponding to this leakage current will occur.

With this perspective, in the present embodiment, a TFT specially designed for the moving image mode and a TFT specially designed for the still image mode are disposed in each pixel, in order to control a transfer time constant, which is obtained as the product of the operating resistances of TFTs and the pixel capacity. In other words, TFTs having different transfer time constants are disposed in each pixel, and a TFT having a predetermined transfer time constant is selected in the moving image mode and in the still image mode. Specifically, the first TFT T1 and the second TFT T2 have different operating resistances, the first TFT T1 being designed for high-speed driving and the second TFT T2 being designed for low-speed driving. The operating resistances of the TFTs are also referred to as on-state resistances of the TFTs. Here, for example in a case where the image capture apparatus is a radiation image capture apparatus used to perform medical X-ray diagnostics, the first TFT T1 is used in the moving image mode where a diagnostic image is read at high speed (at a frame rate of, for example, 30 fps). Also, the second TFT T2 is used in the still image mode where a diagnostic image is read at low speed (high image quality) (at a frame rate of, for example, 0.5 fps). With such a configuration, when reading an image in the moving image mode, the image can be acquired without artifacts by transferring and reading all generated carriers. And when reading an image in the still image mode, the image can be acquired with high quality while minimizing KTC noise and noise related to TFT leakage since no auxiliary capacity needs to be provided, which leads to a reduction in the dose of X-rays. Moreover, reducing the operating resistances of the TFTs also enables a reduction in shot noise generated in accordance with the current flow.

That is, in the present embodiment, disposing individual special-purpose TFTs for the moving image mode and the still image mode enables reliable transfer of a small amount of charge and acquisition of an image with no artifacts in the moving image mode. Moreover, switching to the still image mode enables acquisition of a diagnostic image that reduces all noise including KTC noise, noise related to TFT leakage, and shot noise. Note that the present invention is not limited to a radiation image capture apparatus, but is also applicable in a similar way to, for example, a flat area sensor that is usable in a scanner or the like.

The following describes the transfer capabilities of the aforementioned first TFT T1 and second TFT T2. Although not shown in FIG. 1, the first TFT T1 is, for example, a TFT having a low operating resistance for use in shooting in the moving image mode. Also, the first TFT T1 and the second TFT T2 that are shown in FIG. 1 are both bottom gate type amorphous silicon TFTs as shown in FIG. 3 described later. Amorphous silicon TFTs have lower mobility, namely approximately 0.5 to 1.0 cm²/Vs, than polycrystalline silicon TFTs, but have the advantage of providing the image capture apparatus at low cost because they require a small number of formation processes. However, they have the disadvantage of requiring a large TFT size because of their low mobility. It is thus realistic that the transfer rate of a first TFT T1 (used in the moving image mode) that is within a range that does not reduce the aperture ratio of the conversion element is approximately 1 μs.

In the radiation image capture apparatus, the typical pixel size is approximately 100 to 200 μm, one side of a shooting region is approximately 20 to 40 cm, and the typical number of pixels is approximately 2000 to 3000 pixels per line. In the moving image mode, a speed of approximately 15 to 30 FPS is required, and a time of approximately 10 to 20 μs is necessary to drive a single line. Within this time, (1) the transfer of the electric charge, (2) sampling and holding, (3) the reading of the electric charge, and, in some cases, (4) a reset of pixels are performed, so it is desirable that the time used to transfer the electric charge is about one half of that, namely approximately 5 to 10 μs, and the transfer time constant obtained as a product of the operating resistances of the TFTs and the pixel capacity is approximately one tenth of that, namely approximately 1 to 2 μs. That is, a transfer time constant of approximately 2 μs or less is required for the TFT used in the moving image mode. In the still image mode, it doesn't matter if the transfer speed is low, but a transfer speed that is too low increases the delay from shooting until driving a display and makes it difficult to acquire accurate image acquisition information due to the influence of TFT leakage current. Thus, a speed of approximately 1 to 2 FPS is sufficient, and the time used to drive a single line is approximately 150 to 300 μs. In other words, the desirable transfer time constant obtained as a product of the operating resistances of the TFTs and the pixel capacity is approximately 15 to 30 μs. That is, it is sufficient if the TFT used in the still image mode has a transfer time constant of approximately 10 μs or higher. Furthermore, making the operating resistance of the TFT used in the still image mode different from and higher than that of the TFT used in the moving image mode makes it possible to prevent TFT leakage current and shot noise and thereby results in an improvement in the quality of the acquired image.

From the above, in the case of using an amorphous silicon TFT, the transfer time constant of the first TFT T1 used in the moving image mode is set to 2 μs or less, for example, and the transfer time constant of the second TFT T2 used in the still image mode is set to 10 μs or more, for example. This achieves improvements in the quality of both images acquired in the moving image mode and images acquired in the still image mode. However, the time constant is not limited to this example, and it may vary depending on the number of lines, the frame rate, or the method of sampling and holding or resetting.

It is also desirable that the gate lines G11, . . . , and G1m that are shown in FIG. 1 and used in the moving image mode are configured to have a small line time constant obtained as a product of the line capacity and the line resistance, and the line time constant is less than 2 μs, which is the transfer rate of the first TFT T1. Also, the lines G21, . . . , and G2m used in the still image mode are not required to have a small time constant. However, an appropriate time constant is desired, because too wide lines can cause a reduction in the aperture ratio of the photo-electric conversion element or can cause an increase in the signal line capacity and a resultant increase in noise due to an increase in the area of intersection with the signal line. Similarly, the transistors desirably used as switches in the switching unit 102, have a speed that is sufficiently lower than 2 μs. This switching unit 102 may be formed, using polycrystalline silicon, on an insulating substrate on which the matrix of pixels is arranged or may be formed on a gate driver IC that is connected to the insulating substrate or on a printed circuit board (PCB) serving as the gate driver circuit.

FIG. 2 is an illustrative diagram showing an example in which the same pixels as in FIG. 1 are used and controlled by two gate driver circuits 105 and 106. Gate lines G11, . . . , and G1m used in the moving image mode are controlled with the first gate driver circuit 105, and lines G21, . . . , and G2m used in the still image mode are controlled with the second gate driver circuit 106. Moreover, a switching unit 107 for selecting one of the two gate driver circuits 105 and 106 is provided separately. In the example of FIG. 1, in the case where the switching unit 102 is formed on an insulating substrate, a polycrystalline silicon process is generally used to form the switching unit 102. And in the case where the switching unit 102 is formed in an external circuit outside the insulating substrate, the process becomes difficult because of an increased number of connections between the external circuit and lines in the insulating substrate and narrow spacing between connections. However, the configuration as shown in FIG. 2 does not require the use of a process of forming the switching unit 107 on a substrate with polycrystalline silicon or the like and enables driving from two directions, thereby reducing the number of connections between the external circuit and lines in the insulating substrate on each side and having the advantage of not complicating the connection process.

FIG. 3 is an illustrative diagram of a pixel configured by the photo-electric conversion element C11 and the TFTs T1 and T2 shown in the equivalent circuit diagram of FIG. 1. This pixel includes the photo-electric conversion element C11 composed of a photo-electric conversion layer C11A, a photo-electric conversion element upper electrode C11B, and a photo-electric conversion element lower electrode C11C, and the first and second TFTs T1 and T2 that are connected to the photo-electric conversion element C11. The pixel also includes a signal line S1 that is connected to the photo-electric conversion element C11 via the first TFT T1 and the second TFT T2, a first gate line G11 used to control the first TFT T1, and a second gate line G21 used to control the second TFT T2. The first TFT T1 is used in the moving image mode, and the second TFT T2 is used in the still image mode. As shown, the first TFT T1 has a longer channel width and a shorter channel length than the second TFT T2. This indicates that the first TFT T1 has a low operating resistance and is capable of operating at high speed, and the second TFT T2 has a high operating resistance and is thus capable of preventing shot noise and accordingly reducing TFT leakage current that can result in an increase in noise.

The first gate line G11 used in the moving image mode has a greater line width than the second gate line G21 used in the still image mode. This makes it possible to reduce the line time constant of only the gate line used for moving images. At this time, this becomes meaningless if an increased area of intersection with the signal line S1 or a common electrode line causes an increase in the line capacity and results in an increase in the line time constant, for which reason the area of the intersection may stay the same and the line width may be increased only in a portion where no capacity is formed, for example.

The photo-electric conversion layer C11A may be a PIN photodiode or may be an MIS (metal-insulator semiconductor)-type photo-electric conversion layer. The photo-electric conversion layer may also be made of amorphous selenium or a cadmium-based material that converts X-rays directly into an electric charge. Alternatively, the photo-electric conversion element can be formed overlapping on top of the TFTs if the TFTs and the lines connected to the TFTs are formed first, then for example a low dielectric organic insulation film is formed thereon, and the photo-electric conversion element is further formed thereon. This increases flexibility in the layout of TFTs and facilitates arbitrary settings of the operating resistances, such as reducing or, by contrast, increasing the ratio W/L (where W is the channel width and L is the channel length).

### Second Embodiment

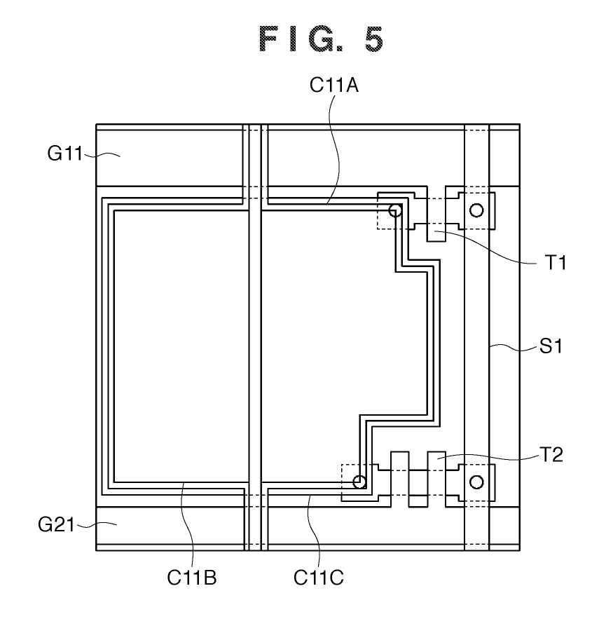

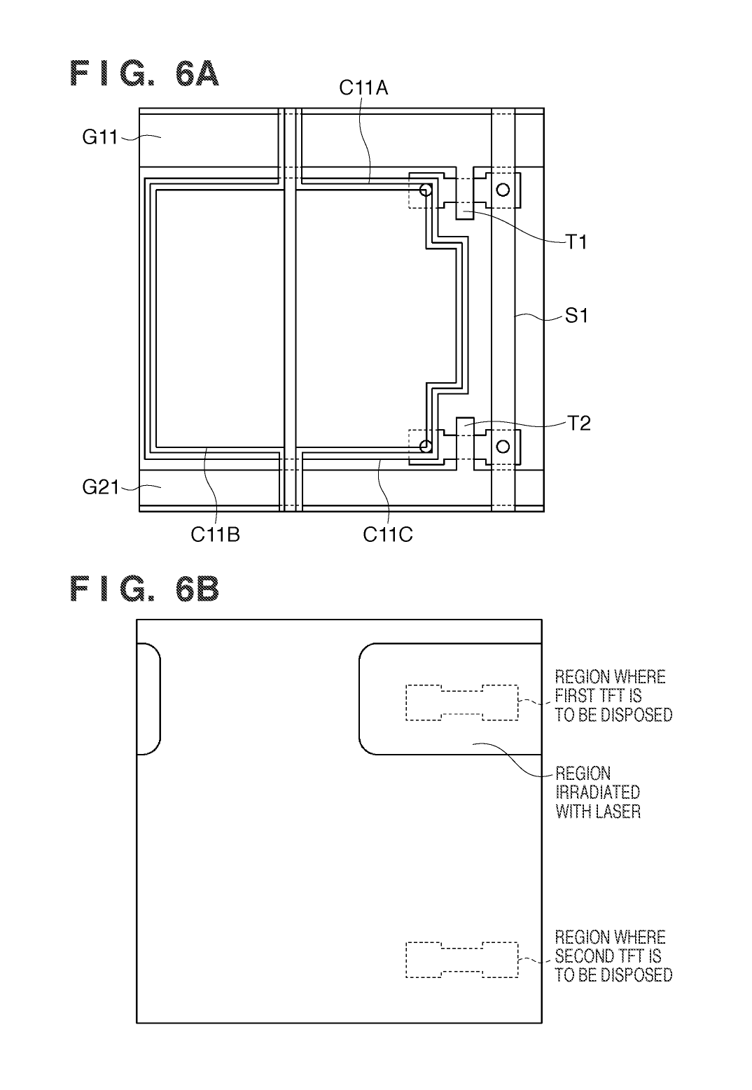

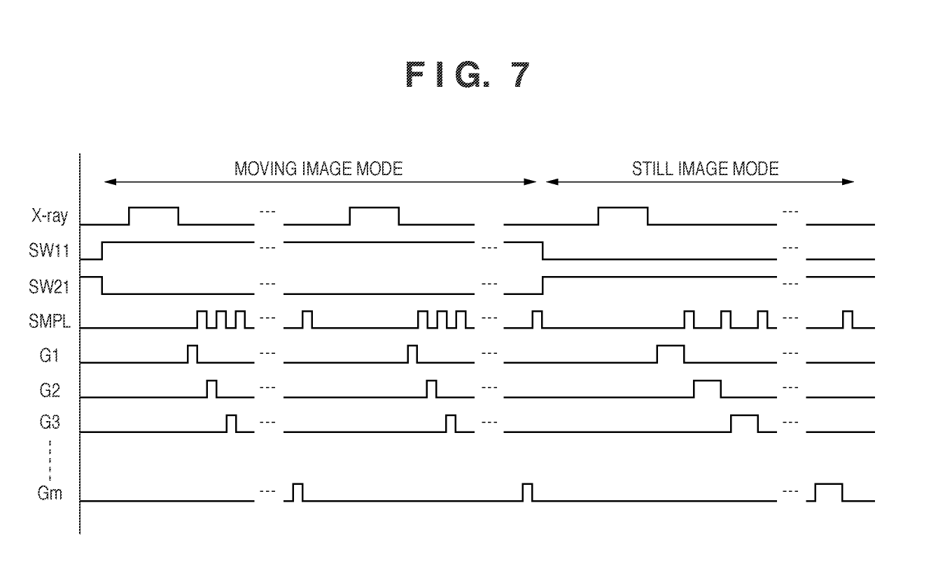

The following describes a second embodiment of the present invention. FIG. 4 is a simplified equivalent circuit diagram of an image capture apparatus according to the second embodiment of the present invention. FIG. 5 is a plan view of a pixel according to the second embodiment of the present invention. FIG. 6A is another plan view of a pixel according to the second embodiment of the present invention pixel, which shows a different example from that in FIG. 5. FIG. 6B is still another plan view of a pixel according to the second embodiment of the present invention, which shows an intermediate step in forming the pixel in FIG. 5. FIG. 7 is a drive timing chart according to the second embodiment of the present invention.

Referring to FIG. 4, a single TFT T1 is connected and used in the moving image mode, and two TFTs T2 are connected in series and used in the still image mode. With such a configuration, leakage current is reduced in the TFTs T2 used in the still image mode, and a still image can be acquired with high quality. Such a configuration is also effective in particular for the case of using polycrystalline silicon TFTs, and the TFTs T2 can be provided with about twice the operating resistance of the TFT T1. The operating resistance is also referred to as an “on-state resistance”. Although there is the possibility of leakage current being increased excessively if the grain boundary in a polycrystalline silicon portion is connected between the source and drain electrodes, even though there is a certain probability that one of the TFTs causes a leakage current through the grain boundary, the series-connection of the two TFTs makes it possible to prevent the occurrence of leakage current with the other TFT. In FIG. 4, while the TFTs T2 are two TFTs that have the same configuration and are connected in series, the number of TFTs may vary, and the channel width W and channel length L of the TFTs T2 may be different from those of the TFT T1, for example the ratio W/L may be lower.

The following describes the transfer capabilities of the first TFT T1 and the second TFTs T2 according to the present embodiment. Although not shown in FIG. 4, for the first TFT T1, for example a TFT may be used that has a low operating resistance for use in shooting in the moving image mode. Also, both the first TFT T1 and the second TFTs T2 that are shown in FIG. 4 are top-gate type polycrystalline silicon TFTs as shown in FIG. 5 described later. Polycrystalline silicon TFTs have higher mobility, namely approximately 50 to 200 cm²/Vs, than amorphous silicon TFTs. Thus, the operating resistance can be reduced with a small TFT, and the transfer rate of the first TFT T1 (used in the moving image mode) can be 0.1 μs or less, for example. However, since the amount of instantaneous current flow increases in inverse proportion to the operating resistance, shot noise caused by this amount of current will increase. Thus, multiple TFTs T2 used in the still image mode are connected in series in order to increase the number of channels, thereby preventing the occurrence of leakage current, increasing the transfer time constant, and reducing noise related to the leakage current and shot noise. The second TFTs T2 used in the still image mode may have a transfer rate of, for example, 1 μs or higher, and in order to achieve this, about five TFTs may be connected in series, for example. Alternatively, the ratio W/L may be adjusted in order to increase the transfer time constant.

Moreover, the operating resistances of the TFT T1 used in the moving image mode and the TFTs T2 used in the still image mode may be changed by changing the average of the volume of the crystal grain included in the TFT and the average grain size of the polycrystalline silicon. As another alternative, the transfer rate may be changed by using polycrystalline silicon for the TFT T1 used in the moving image mode and amorphous silicon for the TFTs T2 used in the still image mode. This can be implemented by, for example, performing selective laser annealing of the top-gate type TFTs, such as performing laser annealing so that an amorphous silicon portion that was formed where the channel portion of the first TFT T1 is formed is transformed into polycrystalline silicon, while not performing laser annealing on locations where the channel portions of the second TFTs T2 are formed. Similarly, the volume and size of crystal grains may be changed by changing the time and direction of the laser annealing and the direction in which the channel is formed, for example. Thus, the average of the volume of the crystal grain included in the TFT or the average grain size in the channel portion of the first TFT T1 may be increased and the average of the volume of the crystal grain included in the TFT or the average grain size in the channel portion of the second TFTs T2 may be reduced.

FIG. 5 is an illustrative diagram of a pixel constituted by the photo-electric conversion element C11 and the TFTs T1 and T2 shown in the equivalent circuit diagram of FIG. 4. This pixel includes the photo-electric conversion element C11 composed of a photo-electric conversion layer C11A, a photo-electric conversion element upper electrode C11B, and a photo-electric conversion element lower electrode C11C, and the first and second TFTs T1 and T2 that are connected to the photo-electric conversion element C11. The pixel also includes a signal line S1 that is connected to the photo-electric conversion element C11 via the first TFT T1 and the second TFT T2, a first gate line G11 used to control the first TFT T1, and a second gate line G21 used to control the second TFT T2. The first TFT T1 is used in the moving image mode, and the second TFT T2 is used in the still image mode. As shown, the first TFT T1 is provided with a single gate electrode, whereas the second TFT T2 is provided with two gate electrodes. As a result, the first TFT T1 and the second TFT T2 have different numbers of channel portions formed under their gate electrode(s), one channel portion for the TFT T1 and two channel portions for the TFT T2. Accordingly, the operating resistance of the first TFT T1 is about half that of the second TFT T2. As described previously, the second TFT T2 may be configured by series-connecting, for example, five TFTs, instead of two TFTs, if space is allowed.

FIGS. 6A and 6B are illustrative diagrams of a pixel configured by the photo-electric conversion element C11 and the TFTs T1 and T2, which shows a different example from that in FIG. 5. The first TFT T1 shown in FIG. 6A is made of polycrystalline silicon, and the second TFT T2 is made of amorphous silicon. As described above, a feature of this pixel is also that a region where TFTs are being formed is divided into a region that is subjected to laser annealing in advance and a region that is not subjected to laser annealing, and TFTs having considerably different operating resistances are formed within a single pixel. Although depending on the pixel size and the accuracy of the laser annealing, the TFTs may in some cases need to be formed in an arrangement that allows a sufficient distance between TFTs. FIG. 6B shows a region of a semiconductor layer that is subjected to laser annealing before forming the TFTs. FIG. 6B shows an example in which laser annealing was performed before forming a semiconductor layer pattern. By performing laser annealing in advance on a region where the first TFT T1 is to be formed, only the first TFT T1 is configured by a polycrystalline silicon TFT, whereas the second TFT T2 is configured by an amorphous silicon TFT, which enables a change in the operating resistance. Alternatively, the operating resistances may also be changed by, for example, changing an irradiation energy of laser so as to change the size and volume of crystal grains between the first TFT T1 and the second TFT T2.

FIG. 7 is a drive timing chart for the image capture apparatus shown in the simplified equivalent circuit diagrams of FIGS. 1 and 4. In the moving image mode, G1 and G11 are connected with SW11, and VL and G21 are connected with SW21, which enables driving in the moving image mode with the first TFT T1. Upon determination of the mode, X-rays are irradiated and the first TFT T1 is driven to transfer electric charge to the signal line S1. The transferred electric charge is sequentially transferred while being sampled and held (SMPL) in a signal processing circuit 103. After the transfer, electric charge of the next line is transferred to the signal line S1. At the time of switching to the still image mode, SW11 and SW21 are toggled so as to start driving with the second TFT T2. At this time, since the second TFT T2 has a higher operating resistance than the first TFT T1, the ON-state voltage application time of the second TFT T2, which is controlled by a shift register, needs to be relatively long.

The photo-electric conversion layer may be a PIN photodiode or may be an MIS (metal-insulator semiconductor)-type photo-electric conversion layer. Also, the photo-electric conversion layer may be made of amorphous selenium or of a cadmium-based material that converts X-rays directly into electric charges.

Furthermore, the TFTs and the lines connected to the TFTs may be formed first, then a low-dielectric organic insulation film, for example, may be formed thereon, and the photo-electric conversion element may be further formed thereon. This makes it possible to form the photo-electric conversion element overlapping on top of the TFTs, thus increasing flexibility in the layout of TFTs, in particular increasing the number of series-connected TFTs, and facilitating arbitrary settings of the operating resistances.

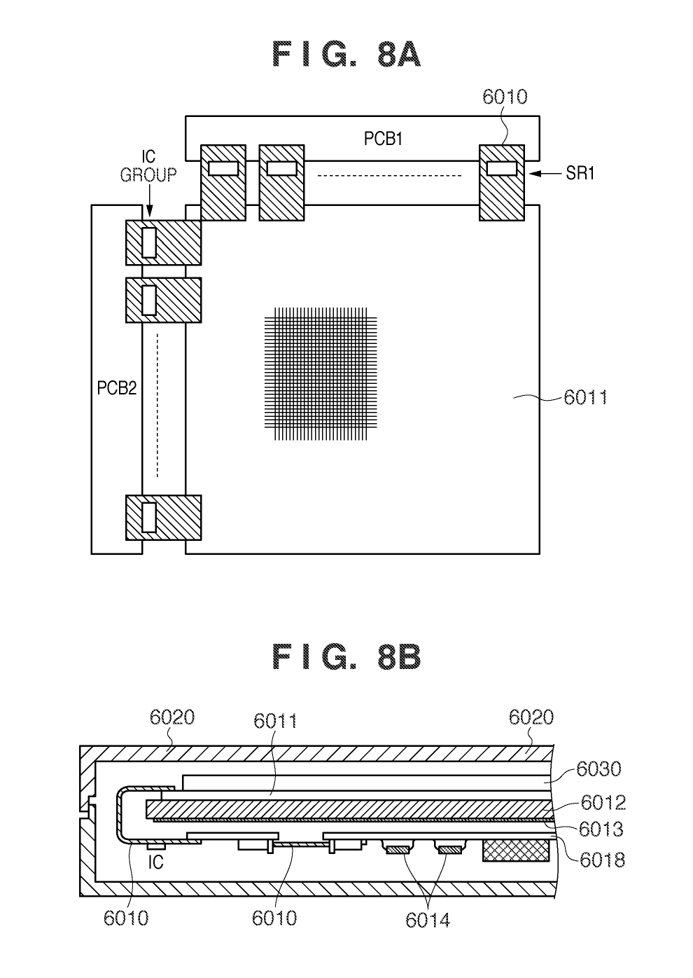

FIGS. 8A and 8B, respectively, are a schematic block diagram and a schematic cross-sectional view of an embodiment of a radiation (X-ray) image capture apparatus according to the present invention. Multiple photo-electric conversion elements and multiple TFTs are formed on a sensor substrate 6011, which is connected to a flexible circuit board 6010 on which shift registers SR1 and integrated circuits IC for detection are mounted. The other side of the flexible circuit board 6010 is connected to circuit boards PCB1 and PCB2. A lead plate 6013 for protecting a memory 6014 in a processing circuit 6018 from X-rays is mounted underneath a base 6012 that constitutes a large photo-electric conversion device with multiple sensor substrates 6011 being adhered thereto. A scintillator (phosphor layer) 6030, such as CsI, for converting X-rays into visible light is evaporated on the sensor substrates 6011. The whole configuration is accommodated in a carbon-fiber case 6020 as shown in FIG. 8B.

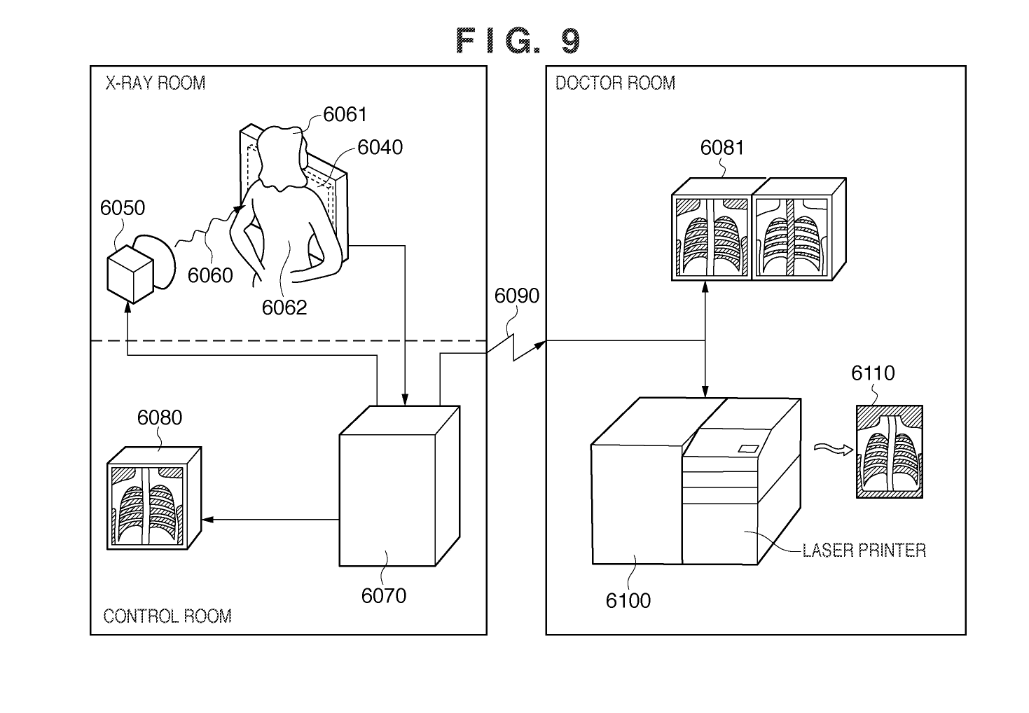

FIG. 9 is an illustrative diagram showing an example in which the X-ray image capture apparatus according to the present invention is applied to an X-ray diagnostic system (radiation image capture system). X-rays 6060 generated from an X-ray tube 6050 (radiation source) are transmitted through a chest 6062 of a patient or subject 6061 and enter a photo-electric conversion device 6040 with a scintillator mounted thereon (a photo-electric conversion device with a scintillator mounted thereon constitutes a radiation image capture apparatus). The incident X-rays include information on the inner parts of the body of the subject (patient) 6061. In response to the incident X-rays, the scintillator emits light, which is then photo-electrically converted into electrical information. This information is converted into a digital signal and subjected to image processing by an image processor 6070, which is signal processing means, so as to be observable on a display 6080, which is display means, in a control room. Note that the radiation image capture system includes at least an image capture apparatus and signal processing means for processing a signal from the image capture apparatus.

It is also noted that the information can be transferred to a remote place with transmission processing means such as a telephone line 6090, and it can be displayed on display means such as a display 6081 in a doctor room in another place or stored in storage means such as an optical disc, enabling a doctor at a remote location to make a diagnosis. The information can also be recorded in a recording medium such as a film 6110 by storage means such as a film processor 6100.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-165049, filed Jul. 13, 2009, which is hereby incorporated by reference herein in its entirety.

What is claimed is:

1. An image capture apparatus comprising:
a plurality of pixels each including a plurality of thin film transistors having different operating resistances and a photo-electric conversion element;
a selection unit configured to select at least one of the plurality of thin film transistors; and
a signal line on which electric charge generated by the photo-electric conversion elements is output via the thin film transistors selected by the selection unit.

2. The image capture apparatus according to claim 1, wherein, among the plurality of thin film transistors, a thin film transistor having a low operating resistance is configured to transfer a moving image and a thin film transistor having a high operating resistance is configured to transfer a still image.

3. The image capture apparatus according to claim 1, wherein, among the plurality of thin film transistors, a thin film transistor having a low operating resistance has a higher ratio (W/L) of channel width (W) to channel length (L) than a thin film transistor having a high operating resistance.

4. The image capture apparatus according to claim 1, wherein, among the plurality of thin film transistors, a thin film transistor having a low operating resistance has a smaller number of channels than a thin film transistor having a high operating resistance.

5. The image capture apparatus according to claim 1, wherein, among the plurality of thin film transistors, a thin film transistor having a low operating resistance has a higher average of a volume of a crystal grain of silicon than a thin film transistor having a high operating resistance.

6. The image capture apparatus according to claim 1, wherein, among the plurality of thin film transistors, a thin film transistor having a low operating resistance has a greater average grain size in a channel portion than a thin film transistor having a high operating resistance.

7. A radiation image capture system comprising:
an image capture apparatus according to claim 1; and
a signal processing unit configured to process a signal from the image capture apparatus.
